(19) United States
(12) Patent Application Publication
(10) Pub. No.: US 2024/0415001 A1
(43) Pub. Date: Dec. 12, 2024

(54) DISPLAY DEVICE MANUFACTURING METHOD

(71) Applicant: Japan Display Inc., Tokyo (JP)

(72) Inventor: Eri SASAKI, Tokyo (JP)

(73) Assignee: Japan Display Inc., Tokyo (JP)

(21) Appl. No.: 18/731,418

(22) Filed: Jun. 3, 2024

(30) Foreign Application Priority Data
Jun. 8, 2023 (JP) 2023-094789

(51) Int. Cl. H10K 71/00; H10K 59/12

(52) U.S. Cl. CPC H10K 71/621; H10K 59/1201

(57) ABSTRACT

According to one embodiment, a display device manufacturing method includes forming a transparent inorganic layer over a display area and a surrounding area which surrounds the display area on a transparent substrate, forming a metal layer on the inorganic layer in the surrounding area, forming an organic layer on the inorganic layer and the metal layer, preparing a processed substrate on which a protective film is attached, on at least the organic layer located directly above the metal layer, irradiating a laser beam from the substrate side toward the metal layer, and forming a plurality of holes penetrating the metal layer and the organic layer, during the irradiating the laser beam.

### CROSS-REFERENCE TO RELATED APPLICATION

This application is based upon and claims the benefit of priority from Japanese Patent Application No. 2023-094789, filed Jun. 8, 2023, the entire contents of which are incorporated herein by reference.

### FIELD

Embodiments described herein relate generally to a display device manufacturing method.

### BACKGROUND

Recently, display devices in which organic light emitting diodes (OLED) are applied as display elements have been put to practical use. In the manufacturing process of such display devices, laser processing is often performed. During the laser processing, when a laser light beam is irradiated toward a workpiece, dust is generated at the irradiated part. If the dust remains adhered to a product, the dust may cause a decrease in reliability of the display device. In addition, if the dust is scattered, a manufacturing device may be contaminated.

In addition, if the dust is collected by a dust collector, the manufacturing equipment needs to have a complex configuration. For this reason, the manufacturing costs may be high.

### BRIEF DESCRIPTION OF THE DRAWINGS

FIG. 1 is a diagram showing a configuration example of a display device DSP.

FIG. 2 is a diagram showing an example of a layout of the sub-pixels SP1, SP2, and SP3.

FIG. 3 is a schematic cross-sectional view showing the display device DSP along line III-III in FIG. 2.

FIG. 4 is a diagram showing an example of the configuration of the tag TG.

FIG. 5 is a schematic cross-sectional view showing the display device DSP along line V-V in

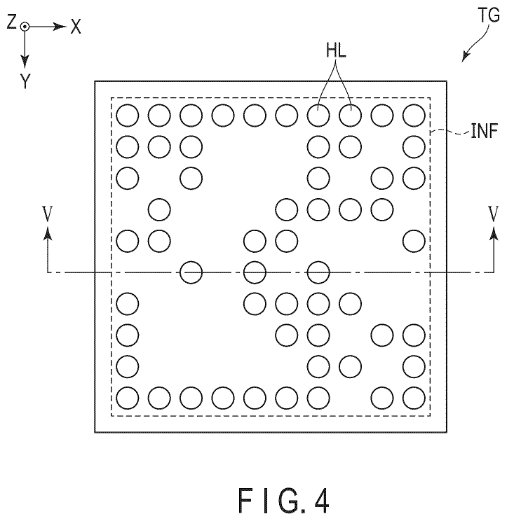

FIG. 4.

FIG. 6 is a flowchart illustrating an example of the method of manufacturing the display device DSP.

FIG. 7 is a diagram illustrating a process of preparing a processed substrate.

FIG. 8 is a diagram illustrating a process of cutting the processed substrate.

FIG. 9 is a diagram illustrating a process of irradiating a laser beam.

FIG. 10 is a diagram illustrating a process of irradiating a laser beam.

FIG. 11 is a diagram illustrating a process of irradiating a laser beam.

FIG. 12 is a diagram illustrating a process of peeling a protective film.

FIG. 13 is a diagram illustrating a process of peeling the protective film.

FIG. 14 is a flowchart illustrating another example of the method of manufacturing the display device DSP.

FIG. 15 is a flowchart illustrating another example of the method of manufacturing the display device DSP.

### DETAILED DESCRIPTION

In general, according to one embodiment, there is provided a display device manufacturing method comprising: forming a transparent inorganic layer over a display area and a surrounding area which surrounds the display area on a transparent substrate; forming a metal layer on the inorganic layer in the surrounding area; forming an organic layer on the inorganic layer and the metal layer; preparing a processed substrate on which a protective film is attached, on at least the organic layer located directly above the metal layer; irradiating a laser beam from the substrate side toward the metal layer; and forming a plurality of holes penetrating the metal layer and the organic layer, during the irradiating the laser beam, wherein the plurality of holes formed in the metal layer are aligned in a pattern corresponding to identification information.

According to another embodiment, there is provided a display device manufacturing method comprising: forming a transparent inorganic layer over a plurality of panel portions on a transparent substrate; forming a metal layer on the inorganic layer in a surrounding area surrounding a display area, in each of the panel portions; forming an organic layer on the inorganic layer and the metal layer; preparing a processed substrate on which a protective film is attached, on at least the organic layer located directly above the metal layer; irradiating a laser beam from the substrate side toward the metal layer; and forming a plurality of holes penetrating the metal layer and the organic layer, during the irradiating the laser beam, wherein the plurality of holes formed in the metal layer are aligned in a pattern corresponding to identification information.

According to yet another embodiment, there is provided a display device manufacturing method comprising: forming a metal layer above a substrate; arranging a protective film directly above the metal layer; irradiating a laser beam from the substrate side toward the metal layer; and forming a plurality of holes aligned in a pattern corresponding to identification information, in the metal layer, during the irradiating the laser beam.

According to each of the embodiments, a display device manufacturing method capable of suppressing reduction in reliability and reducing the manufacturing costs can be provided.

An embodiment will be described hereinafter with reference to the accompanying drawings.

The disclosure is merely an example, and proper changes within the spirit of the invention, which are easily conceivable by a person of ordinary skill in the art, are included in the scope of the invention as a matter of course. To more clarify the explanations, the drawings may pictorially show width, thickness, shape and the like of each portion as compared with actual embodiments, but they are mere examples and do not restrict the interpretation of the invention. In addition, in the specification and drawings, structural elements which function in the same or a similar manner to those described in connection with preceding drawings are denoted by like reference numbers, detailed description thereof being omitted unless necessary.

In the drawings, an X-axis, a Y-axis and a Z-axis orthogonal to each other are described to facilitate understanding as needed. A direction along the X-axis is referred to as a first direction, a direction along the Y-axis is referred to as a second direction, and a direction along the Z-axis is referred to as a third direction. Viewing various elements parallel to the third direction Z is referred to as plan view.

The display device of the present embodiment is, for example, an organic electroluminescent display device comprising an organic light emitting diode (OLED) as a display element, and can be mounted on televisions, personal computers, vehicle-mounted devices, tablet terminals, smartphones, mobile phones, and the like.

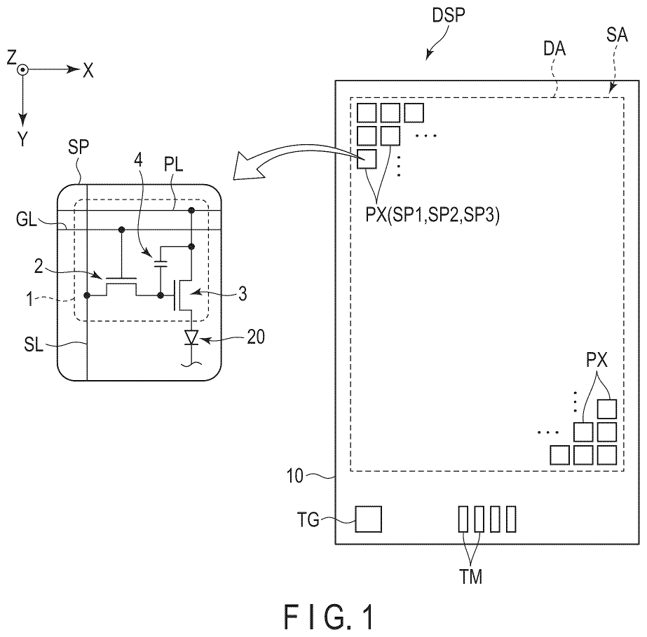

FIG. 1 is a diagram showing a configuration example of a display device DSP. The display device DSP has a display area DA on which images are displayed and a surrounding area SA surrounding the display area DA, on an insulating substrate 10. The substrate 10 is a glass substrate. Incidentally, the material of the substrate 10 is not limited to the glass substrate, but can be any material with high transmittance to ultraviolet wavelengths.

The display area DA includes a plurality of pixels PX arrayed in a matrix in the first direction X and the second direction Y. The pixel PX comprises a plurality of sub-pixels SP. In one example, the pixel PX comprises a red sub-pixel SP1, a green sub-pixel SP2, and a blue sub-pixel SP3. Incidentally, the pixel PX may comprise four or more sub-pixels including a sub-pixel of the other color such as white in addition to the sub-pixels of the above three colors.

The surrounding area SA includes a tag TG and a plurality of terminals TM aligned in the first direction X. In the example of FIG. 1, the tag TG and the plurality of terminals TM are located on an arrow side of the second direction Y with respect to the display area DA. The tag TG has, for example, a pattern corresponding to identification information of the display device DSP, which will be described in detail below. The pattern corresponding to the identification information is formed as a two-dimensional code. Such a pattern is marked with a laser beam to be described below. The plurality of terminals TM are connected to flexible printed circuit boards, IC chips, and the like. In addition, the plurality of terminals TM are electrically connected to various wires (scanning lines GL, signal lines SL, power lines PL, etc.) for driving the sub-pixels SP.

The sub-pixel SP comprises a pixel circuit 1 and a display element 20 driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

In the pixel switch 2, a gate electrode is connected to the scanning line GL. Either of a source electrode and a drain electrode of the pixel switch 2 is connected to the signal line SL, and the other is connected to a gate electrode of the drive transistor 3, and the capacitor 4. In the drive transistor 3, either of the source and the drain electrode is connected to the power line PL and the capacitor 4, and the other is connected to an anode of the display element 20. Incidentally, the configuration of the pixel circuit 1 is not limited to the example shown in the drawing.

The display element 20 is an organic light emitting diode (OLED) as a light emitting element. For example, the sub-pixel SP1 comprises a display element 20 that irradiates light corresponding to a red wavelength, the sub-pixel SP2 comprises a display element 20 that irradiates light corresponding to a green wavelength, and the sub-pixel SP3 comprises a display element 20 that irradiates light corresponding to a blue wavelength. The configuration of the display element 20 will be described below.

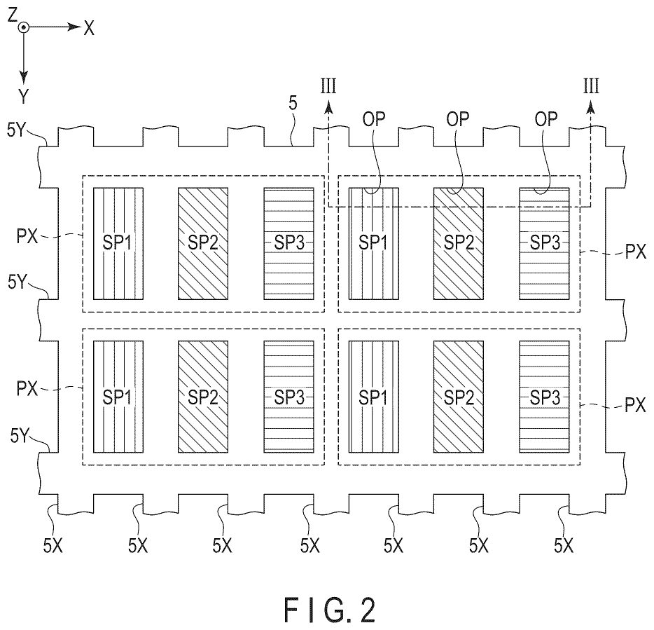

FIG. 2 is a diagram showing an example of a layout of the sub-pixels SP1, SP2, and SP3. Four pixels PX surrounded by dashed lines. In each of the pixels PX, the sub-pixels SP1, SP2, and SP3 are aligned in this order in the first direction X. In other words, a column composed of a plurality of sub-pixels SP1 aligned in the second direction Y, a column composed of a plurality of sub-pixels SP2 aligned in the second direction Y, and a column composed of a plurality of sub-pixels SP3 aligned in the second direction Y are aligned in the first direction X, in the display area DA.

A partition 5 is arranged at the boundary of the sub-pixels SP1, SP2, and SP3. In the example shown FIG. 2, the partition 5 is formed in a grating shape including a plurality of partitions 5X each located between sub-pixels SP adjacent in the first direction X and a plurality of partitions 5Y each located between sub-pixels SP adjacent in the second direction Y. In the example shown in FIG. 2, the partitions 5X extend parallel to the second direction Y and the partitions 5Y extend parallel to the first direction X. An aperture OP is formed in each of the sub-pixels SP1, SP2, and SP3, by the partitions 5X and 5Y. Such an aperture OP corresponds to the light irradiation area of each sub-pixel SP. In the illustrated example, the area of the aperture OP in each sub-pixel SP is the same.

Incidentally, the layout of the sub-pixels is not limited to the illustrated example. For example, the area of the aperture OP in each sub-pixel SP may be different from each other. In addition, the sub-pixels SP1, SP2, and SP3 may not be aligned in a row. Furthermore, sub-pixels SP of colors different from each other may be aligned in the second direction Y.

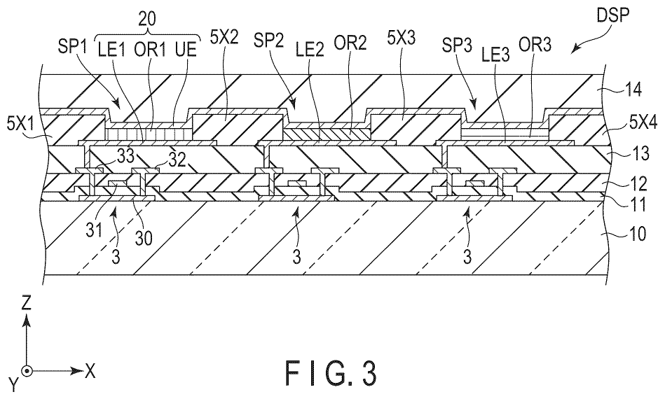

FIG. 3 is a schematic cross-sectional view showing the display device DSP along line III-III in FIG. 2. In FIG. 3, the drive transistor 3 and the display element 20 are shown as the elements arranged in the sub-pixels SP1, SP2, and SP3, and illustration of the other elements is omitted.

The display device DSP comprises the substrate 10, insulating layers 11, 12, and 13, the partitions 5X, and a sealing layer 14. The insulating layers 11, 12, and 13 are stacked on the substrate 10 in the third direction Z. For example, the insulating layers 11 and 12 are inorganic layers formed of inorganic materials, and the insulating layer 13 and the partitions 5X are organic layers formed of organic materials. The partitions 5Y shown in FIG. 2 are formed of the same material as the partitions 5X, integrally with the partitions 5X.

The drive transistor 3 of each sub-pixel comprises a semiconductor layer 30 and electrodes 31, 32, and 33. The electrode 31 corresponds to the gate electrode. Either of the electrodes 32 and 33 corresponds to the source electrode, and the other corresponds to the drain electrode. The semiconductor layer 30 is arranged between the substrate 10 and the insulating layer 11. The electrode 31 is arranged between the insulating layers 11 and 12. The electrodes 32 and 33 are arranged between the insulating layers 12 and 13, and are in contact with the semiconductor layer 30 through contact holes which penetrate the insulating layers 11 and 12.

Incidentally, the configuration of the drive transistor 3 is not limited to the top-gate type shown in the drawing, but may be the bottom-gate type.

The semiconductor layer 30 may be formed of polycrystalline silicon, amorphous silicon, oxide semiconductor, or the like. The electrode 31 is formed of, for example, an alloy of molybdenum and tungsten. The electrodes 32 and 33 are formed as, for example, a multilayer body of a titanium layer and an aluminum layer or a multilayer body of a molybdenum layer and an aluminum layer.

The display element 20 comprises a lower electrode LE, an organic EL layer OR, and an upper electrode UE. The lower electrode LE is an electrode arranged for each sub-pixel SP and may be referred to as a pixel electrode. The upper electrode UE is an electrode arranged commonly to the plurality of display elements 20 and may be referred to as a common electrode. The organic EL layer OR is arranged between the lower electrode LE and the upper electrode UE.

The lower electrodes LE1, LE2, and LE3 are arranged on the insulating layer 13. The partitions 5X1, 5X2, 5X3, and 5X4 are also arranged on the insulating layer 13. In the example of FIG. 3, the partitions 5X1 and 5X2 cover both ends of the lower electrode LE1 in the first direction X, the partitions 5X2 and 5X3 cover both ends of the lower electrode LE2 in the first direction X, and the partitions 5X3 and 5X4 cover both ends of the lower electrode LE3 in the first direction X. Although not shown in the cross-section in FIG. 3, the partitions 5Y are also arranged on the insulating layer 13 similarly to the partitions 5X, and cover the ends of the lower electrodes LE1, LE2, and LE3 in the second direction Y. In plan view, the lower electrodes LE1, LE2, and LE3 overlap with the apertures OP shown in FIG. 2, respectively.

The lower electrodes LE1, LE2, and LE3 are electrically connected to the electrodes 33 through contact holes that penetrate the insulating layer 13, respectively. The lower electrodes LE1, LE2, and LE3 are formed of a metallic material such as silver. However, the lower electrodes LE1, LE2, and LE3 may be formed of a transparent conductive material such as indium tin oxide (ITO) or indium zinc oxide (IZO) or may be multilayer bodies of a transparent conductive material and a metal material.

The organic EL layer OR1 is located between the partitions 5X1 and 5X2 in the first direction X, includes a red light irradiating layer, and covers the lower electrode LE1. The organic EL layer OR2 is located between the partitions 5X2 and 5X3 in the first direction X, includes a green light irradiating layer, and covers the lower electrode LE2. The organic EL layer OR3 is located between the partitions 5X3 and 5X4 in the first direction X, includes a blue light irradiating layer, and covers the lower electrode LE3. Although not shown in the cross-section in FIG. 3, the organic EL layers OR1, OR2, and OR3 are located between the partitions 5Y adjacent in the second direction Y. In other words, the organic EL layers OR1, OR2, and OR3 are arranged in the apertures OP shown in FIG. 2 in plan view, respectively.

In addition, although not described in detail, each of the organic EL layers OR1, OR2, and OR3 includes functional layers such as a hole injection layer, a hole transport layer, an electron injection layer, and an electron transport layer.

The upper electrode UE covers the organic EL layers OR1, OR2, and OR3 and the partitions 5X1, 5X2, 5X3, and 5X4. The upper electrode UE is formed of metallic materials such as magnesium and silver. However, the upper electrode UE may be formed of a transparent conductive material such as ITO or IZO.

The sealing layer 14 is arranged on the upper electrode UE. The sealing layer 14 includes an organic layer which planarizes the unevenness caused by the partitions 5X1, 5X2, 5X3, and 5X4, and an inorganic layer which protects the organic EL layers OR1, OR2, OR3, OR4 from moisture and the like. The organic layer is formed to be thicker than, for example, the insulating layers 11, 12, and 13 and the partitions 5X1, 5X2, 5X3, and 5X4.

FIG. 4 is a diagram showing an example of the configuration of the tag TG.

In the example of FIG. 4, the tag TG is formed in a square shape. The tag TG is a metal layer located in the same layer as the electrode 31 shown in FIG. 3 or a metal layer located in the same layer as the electrodes 32 and 33, and is formed of at least one of materials such as titanium, molybdenum, tungsten, and aluminum. In one example, the tag TG is located in the same layer as the electrodes 32, and the like and is formed as a multilayer body of a titanium layer and an aluminum layer or a multilayer body of a molybdenum layer and an aluminum layer.

The tag TG has identification information INF. The identification information INF is formed as a pattern of a plurality of holes HL that penetrate the tag TG in the third direction Z. The plurality of holes HL are arranged in the first direction X and the second direction Y according to predetermined rules to form a two-dimensional code. By reading the identification information INF with a scanner or the like, information necessary for product management, such as the serial number or lot number of a product registered in advance, can be obtained.

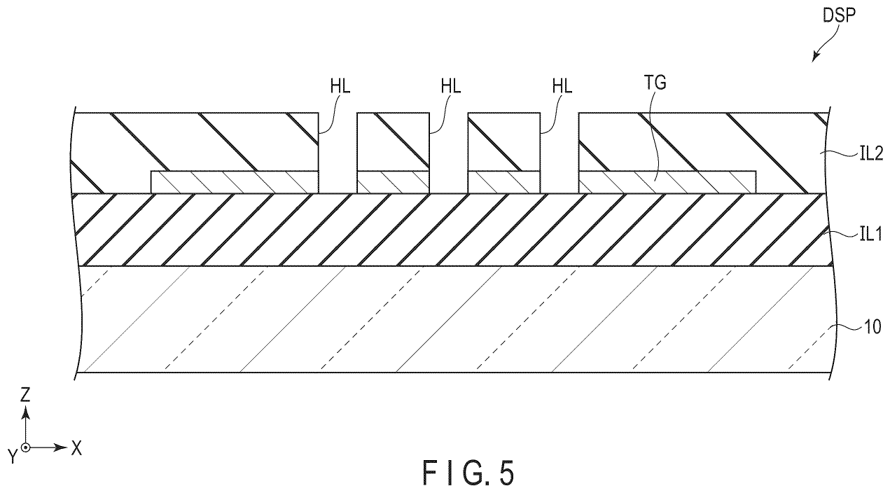

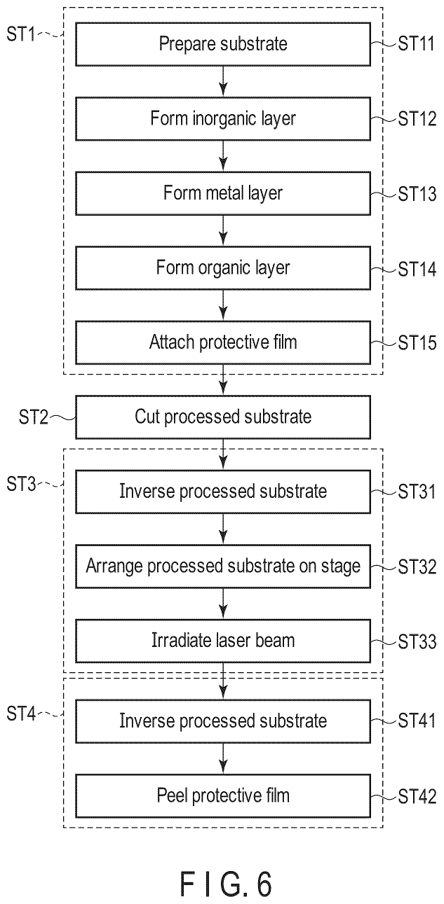

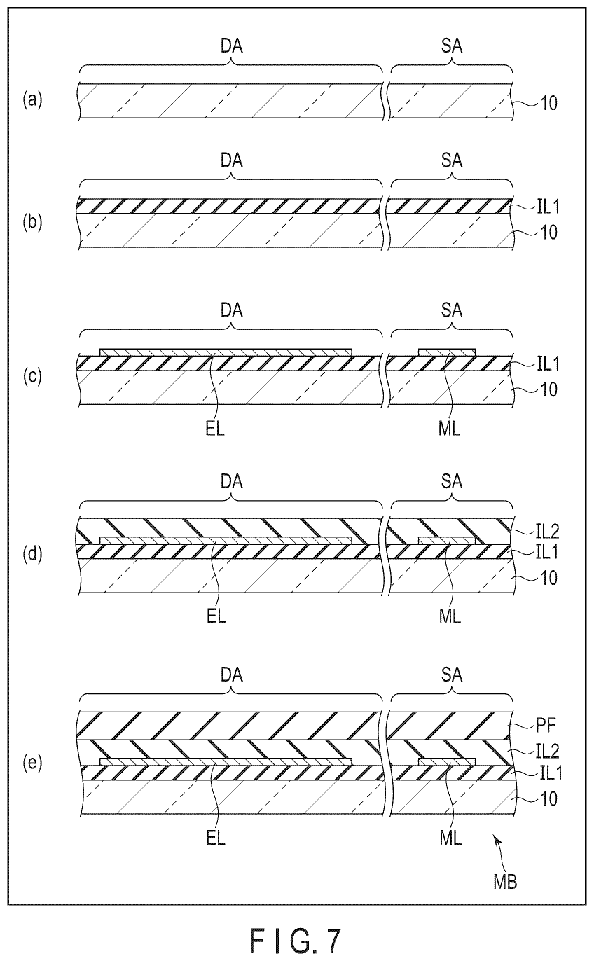

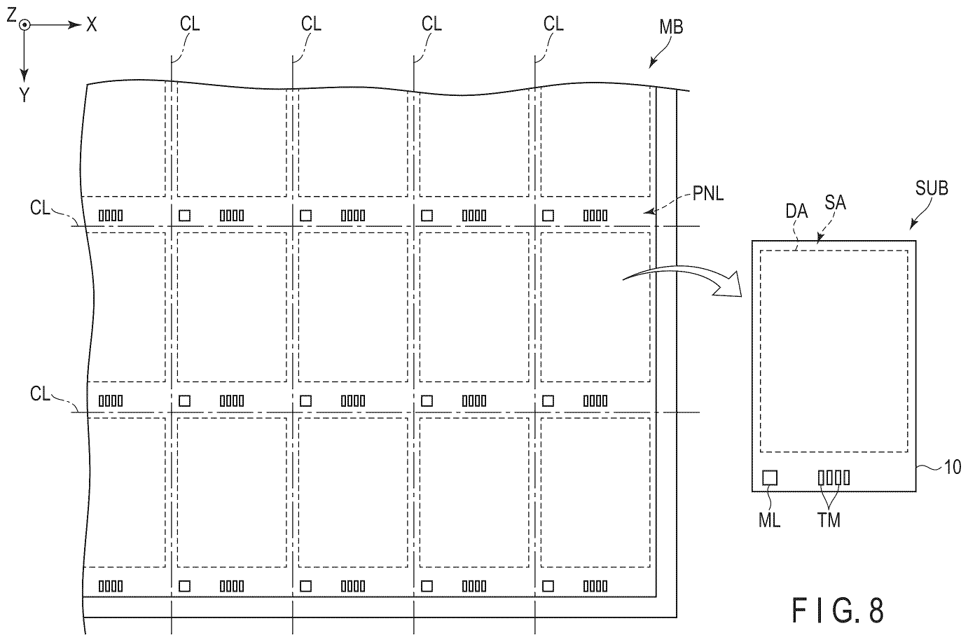

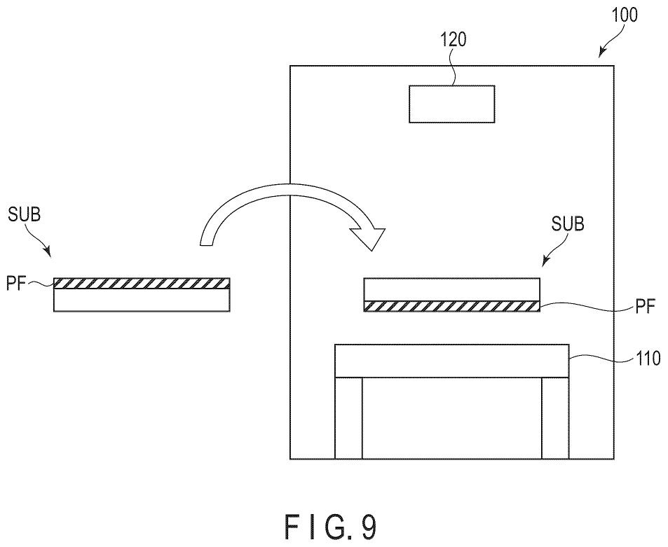

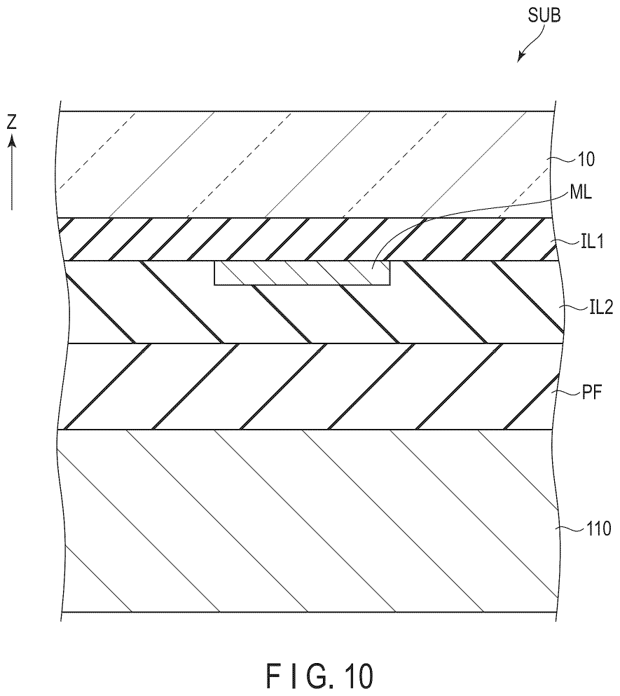

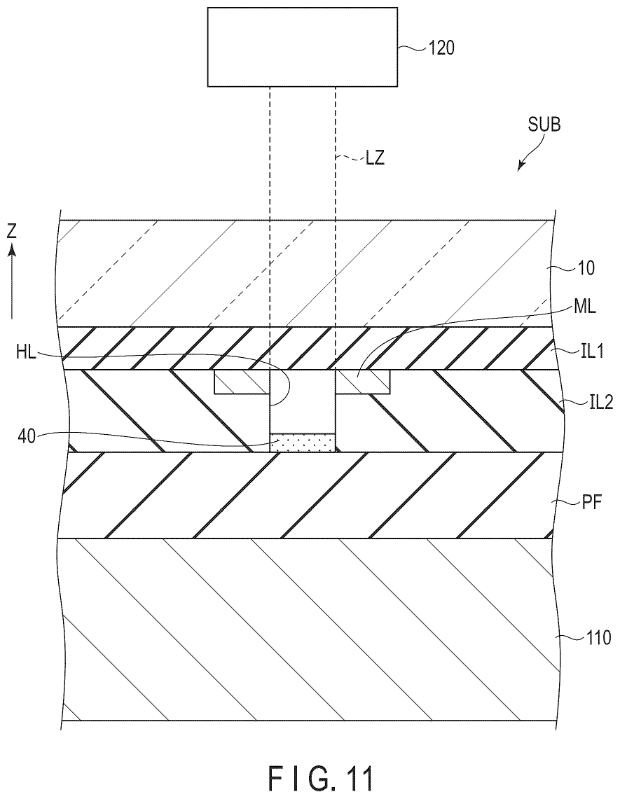

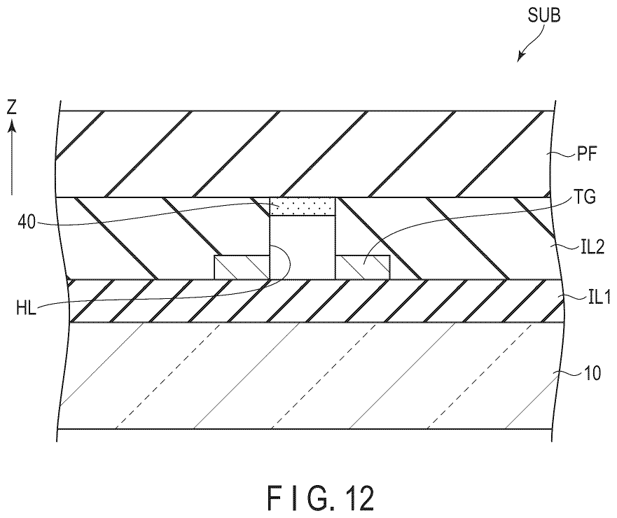

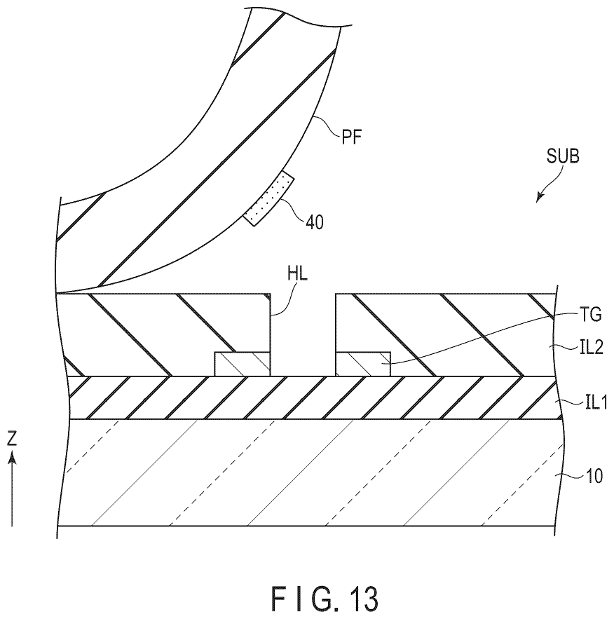

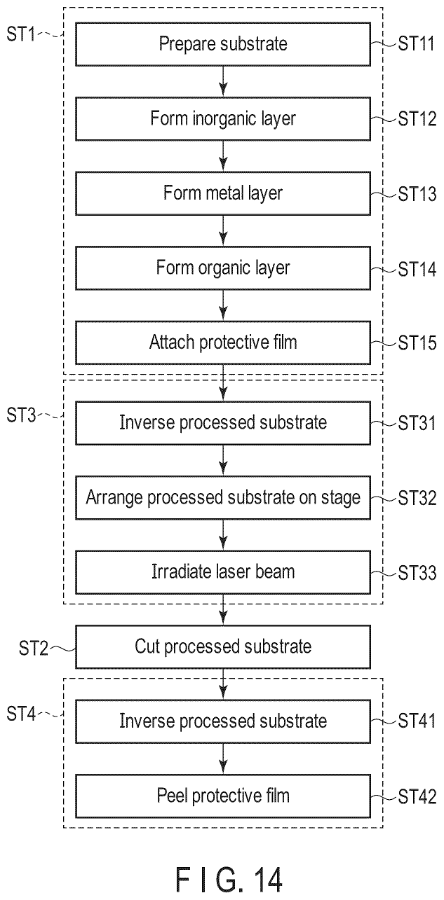

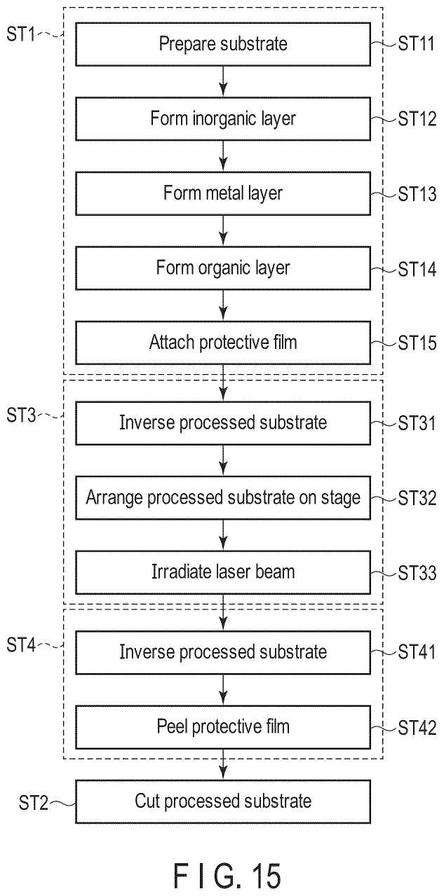

FIG. 5 is a schematic cross-sectional view showing the display device DSP including the tag TG along line V-V in FIG. 4.

The display device DSP includes insulating layers IL1 and IL2. The insulating layer IL1 is an inorganic layer formed of a transparent inorganic material. The insulating layer IL1 corresponds to, for example, at least one of the insulating layers 11 and 12 shown in FIG. 3. The insulating layer IL2 is an organic layer formed of a transparent organic material. The insulating layer IL2 corresponds to, for example, at least one of the organic layers included in the partition 5 in FIG. 2, the insulating layer 13 in FIG. 3, and the sealing layer 14.

The insulating layer IL1 is arranged on the substrate 10. The tag TG is arranged on the insulating layer IL1. The insulating layer IL2 is arranged on the tag TG and the insulating layer IL1. Each of the plurality of holes HL penetrates the insulating layer IL2 and the tag TG to reach the insulating layer IL1. The holes HL do not penetrate the insulating layer IL1.

Next, an example of a method of manufacturing the display device DSP will be described with reference to FIG. 6 to FIG. 13.

FIG. 6 is a flowchart illustrating an example of the method of manufacturing the display device DSP.

The manufacturing method shown in the drawing, roughly, includes a process of preparing a large-sized processed substrate MB including a plurality of panel portions PNL (step ST1), a process of cutting the processed substrate MB (step ST2), a process of irradiating a laser beam LZ (step ST3), and a process of peeling a protective film PF (step ST4).

In step ST1, first, a large substrate 10 is prepared as shown in FIG. 7(a) (step ST11). The substrate 10 is, for example, a glass substrate.

After that, as shown in FIG. 7(b), the insulating layer IL1 which is an inorganic layer is formed on the substrate 10 (step ST12). The insulating layer IL1 is formed over the display area DA and the surrounding area SA on the substrate 10. The insulating layer IL1 is formed of, for example, a transparent inorganic material such as silicon nitride (SiNx), silicon oxide (SiOx) or silicon oxynitride (SiON).

After that, as shown in FIG. 7(c), a metal layer ML is formed on the insulating layer IL1 in the surrounding area SA (step ST13). In the illustrated example, the electrode EL is formed on the insulating layer IL1 in the display area DA at the same time as formation of the metal layer ML.

More specifically, first, at least one metal material of titanium, molybdenum, tungsten, and aluminum is deposited on the insulating layer IL1 to form a metal thin film. After that, resist is formed in the area to be left as the electrode EL and the metal layer ML. Then, the metal thin film is etched by using the resist as a mask. After that, the resist is removed. As a result, the electrode EL and the metal layer ML are formed. In other words, the electrode EL and the metal layer ML are formed of the same material in the same process.

For example, the electrode EL corresponds to the electrodes 32 and 33 in FIG. 3, and the electrode EL and the metal layer ML are formed as a multilayer body of a titanium layer and an aluminum layer or a multilayer body of a molybdenum layer and an aluminum layer.

After that, as shown in FIG. 7(d), the insulating layer IL2 which is the organic layer is formed on the insulating layer IL1, the electrode EL, and the metal layer ML (step ST14).

In addition to the pixel circuit 1 and the display element 20 in the display area DA, the terminals TM in the surrounding area SA, and the like are formed, in step ST12 through step ST14.

Then, as shown in FIG. 7(e), the protective film PF is attached onto the insulating layer IL2 (step ST15). At this time, the protective film PF is arranged on the insulating layer IL2 which is located at least directly above the metal layer ML. In the illustrated example, the protective film PF is arranged over the display area DA and the surrounding area SA, overlapping with the entire insulating layer IL2.

The protective film PF is formed of, for example, a resin material such as polyethylene terephthalate (PET).

The processed substrate MB is thereby prepared. The processed substrate MB thus prepared includes a plurality of panel portions PNL aligned in the first direction X and the second direction Y, as shown in FIG. 8. In the example of FIG. 8, the plurality of panel portions PNL are adjacent to each other in the first direction X and the second direction Y across cut lines CL represented by one-dot chain lines. Incidentally, a gap may be provided between the panel portions PNL.

In step ST2, as shown in FIG. 8, the processed substrate MB is cut for each panel portion PNL along the cut lines CL. A single processed substrate SUB thereby formed.

In step ST3, the processed substrate SUB is first carried in a laser irradiation device 100, as shown in FIG. 9. The laser irradiation device 100 comprises a stage 110 and a laser device 120 arranged above the stage 110.

When the processed substrate SUB is carried in the laser irradiation device 100, the processed substrate SUB is inverted such that the protective film PF of the processed substrate SUB faces the stage 110 (step ST31).

Then, as shown in FIG. 10, the processed substrate SUB is arranged on the stage 110 (step ST32). At this time, the processed substrate SUB is arranged on the stage 110 such that the protective film PF is in contact with the stage 110. FIG. 10 through FIG. 13 show an enlarged cross-section of a portion of the processed substrate SUB, which includes the metal layer ML.

After that, as shown in FIG. 11, the laser beam LZ is irradiated toward the processed substrate SUB (step ST33). At this time, the laser device 120 is located on a side of the processed substrate SUB, which faces the substrate 10. The laser device 120 is configured to irradiate the laser beam LZ having a wavelength which is mainly suitable for processing the metal layer ML and which penetrates the substrate 10 and the insulating layer IL1. For example, the laser device 120 is configured to irradiate a laser beam LZ of a UV wavelength. In addition, at this time, the protective film PF is in contact with the stage 110 at the position of emission of the laser beam LZ.

The laser device 120 irradiates the laser beam LZ from the substrate 10 side toward the metal layer ML. The laser beam LZ penetrates the substrate 10 and the insulating layer IL1, which are formed of a transparent material, and forms the holes HL which penetrate the metal layer ML and the insulating layer IL2. Most of the energy of the laser beam LZ is used to process the metal layer ML and the insulating layer IL2. For this reason, the laser beam LZ does not form holes which penetrate the protective film PF, and the stage 110 is hardly damaged by the laser beam LZ. In addition, when the laser beam LZ forms the holes HL, dust 40 is generated. The dust 40 adheres to the protective film PF directly above the metal layer ML.

A plurality of holes HL in a pattern corresponding to the identification information are formed in the metal layer ML by such emission of the laser beam LZ. The tag TG shown in FIG. 4 or the like is thereby formed.

In step ST4, the processed substrate SUB is first carried out from the laser irradiation device 100, and the processed substrate SUB is inverted as shown in FIG. 12 (step ST41).

Then, as shown in FIG. 13, the protective film PF is peeled from the processed substrate SUB (step ST42). Since the dust 40 adheres to the protective film PF, the dust 40 is removed from the processed substrate SUB by peeling the protective film PF from the processed substrate SUB.

In the above processes, a plurality of holes HL aligned in the pattern corresponding to the identification information are formed in the metal layer ML and the insulating layer IL2 by the emission of the laser beam.

Incidentally, as shown in FIG. 14, a process of cutting the processed substrate MB for each panel portion PNL (step ST2) may be performed after the process of irradiating the laser beam (step ST3). For example, a laser beam may be irradiated to a plurality of tags TG in the processed substrate MB, and then the processed substrate MB may be cut for each panel portion PNL, in a plurality of laser facilities.

In addition, as shown in FIG. 15, the process of cutting the processed substrate MB for each panel portion PNL (step ST2) may be performed after the process of peeling the protective film PF (step ST4). In this case, the protective film PF is peeled from the processed substrate MB in step ST42. When the protective film PF is peeled from the processed substrate MB, the number of times to peel the protective film PF is reduced as compared to the case where the protective film PF is peeled from the processed substrate SUB which is cut for each panel portion PNL. As a result, the manufacturing yield of the display device can be improved.

According to the present embodiment, the dust 40 generated by laser irradiation to form the tag TG adheres to the protective film PF. Scattering of the dust generated during the laser irradiation can be thereby suppressed. Therefore, the manufacturing costs of the display device can be reduced since facilities such as a dust collector for vacuuming the dust are unnecessary.

Furthermore, the laser beam LZ is not transmitted through the protective film PF, and the stage 110 is hardly damaged by the laser beam LZ. As a result, for example, a stage with a through hole or groove formed at the laser irradiation position does not need to be prepared. Therefore, the manufacturing costs of the display device can be reduced.

Furthermore, the dust 40 adhering to the protective film PF is removed from the processed substrate SUB together with the protective film PF. As a result, the dust 40 hardly remains on the processed substrate SUB. Therefore, the reduction in reliability of the display device can be suppressed.

In addition, the scattering of dust 40 is suppressed and the generated dust is removed from the processed substrate SUB together with the protective film PF, thereby suppressing contamination of the laser irradiation device 100.

Furthermore, the tag TG formed by the manufacturing method described above can be formed in a small space and is suitable for the display device DSP in which the surrounding area SA has small area.

As described above, according to the present embodiment, a display device manufacturing method capable of suppressing the reduction in reliability and reducing the manufacturing costs can be provided.

Incidentally, in the above embodiment, an organic electroluminescent display device has been described as an example of the display device DSP, but the display device DSP may be a display device comprising a liquid crystal element or an inorganic light emitting diode as a display element.

All of the methods of manufacturing display devices that can be implemented by a person of ordinary skill in the art through arbitrary design changes to the methods of manufacturing display devices described above as embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, additions, deletions or changes in design of the constituent elements or additions, omissions, or changes in condition of the processes arbitrarily conducted by a person of ordinary skill in the art, in the above embodiments, fall within the scope of the present invention as long as they are in keeping with the spirit of the present invention.

In addition, the other advantages of the aspects described in the embodiments, which are obvious from the descriptions of the present specification or which can be arbitrarily conceived by a person of ordinary skill in the art, are considered to be achievable by the present invention as a matter of course.

What is claimed is:

1. A display device manufacturing method comprising:
forming a transparent inorganic layer over a display area and a surrounding area which surrounds the display area on a transparent substrate;
forming a metal layer on the inorganic layer in the surrounding area;
forming an organic layer on the inorganic layer and the metal layer;
preparing a processed substrate on which a protective film is attached, on at least the organic layer located directly above the metal layer;
irradiating a laser beam from the substrate side toward the metal layer; and
forming a plurality of holes penetrating the metal layer and the organic layer, during the irradiating the laser beam, wherein
the plurality of holes formed in the metal layer are aligned in a pattern corresponding to identification information.

2. The display device manufacturing method of claim 1, wherein
the irradiating the laser beam is performed in a state in which the protective film is in contact with a stage.

3. The display device manufacturing method of claim 2, wherein
the protective film is in contact with the stage at the laser beam irradiation position during the irradiating the laser beam.

4. The display device manufacturing method of claim 1, wherein
during the irradiating the laser beam, a hole penetrating the protective film is not formed, but dust generated by forming the hole penetrating the metal layer and the organic layer adheres to the protective film.

5. The display device manufacturing method of claim 4, wherein
the protective film is peeled from the processed substrate after irradiating the laser beam.

6. The display device manufacturing method of claim 1, wherein
the laser beam is a laser beam of a UV wavelength.

7. The display device manufacturing method of claim 1, wherein
the substrate is a glass substrate, and
the inorganic layer is formed of silicon nitride (SiNx), silicon oxide (SiOx) or silicon oxynitride (SiON).

8. The display device manufacturing method of claim 1, wherein
the metal layer is formed of at least one material of titanium, molybdenum, tungsten, and aluminum.

9. The display device manufacturing method of claim 1, further comprising:
forming an electrode on the inorganic layer in the display area, wherein
the electrode and the metal layer are formed in a same process.

10. The display device manufacturing method of claim 9, wherein
the metal layer is formed as a multilayer body of a titanium layer and an aluminum layer or a multilayer body of a molybdenum layer and an aluminum layer.

11. A display device manufacturing method comprising:
forming a transparent inorganic layer over a plurality of panel portions on a transparent substrate;
forming a metal layer on the inorganic layer in a surrounding area surrounding a display area, in each of the panel portions;
forming an organic layer on the inorganic layer and the metal layer;
preparing a processed substrate on which a protective film is attached, on at least the organic layer located directly above the metal layer;
irradiating a laser beam from the substrate side toward the metal layer; and
forming a plurality of holes penetrating the metal layer and the organic layer, during the irradiating the laser beam, wherein
the plurality of holes formed in the metal layer are aligned in a pattern corresponding to identification information.

12. The display device manufacturing method of claim 11, wherein
the processed substrate is cut for each of the panel portions before irradiating the laser beam.

13. The display device manufacturing method of claim 11, wherein
the processed substrate is cut for each of the panel portions after irradiating the laser beam.

14. The display device manufacturing method of claim 11, wherein
the irradiating the laser beam is performed in a state in which the protective film is in contact with a stage.

15. The display device manufacturing method of claim 11, wherein
during the irradiating the laser beam, a hole penetrating the protective film is not formed, but dust generated by forming the hole penetrating the metal layer and the organic layer adheres to the protective film, and
the protective film is then peeled from the processed substrate.

16. The display device manufacturing method of claim 11, wherein
the laser beam is a laser beam of a UV wavelength,
the substrate is a glass substrate,
the inorganic layer is formed of silicon nitride (SiNx), silicon oxide (SiOx) or silicon oxynitride (SiON), and
the metal layer is formed of at least one material of titanium, molybdenum, tungsten, and aluminum.

17. A display device manufacturing method comprising:
forming a metal layer above a substrate;
arranging a protective film directly above the metal layer;
irradiating a laser beam from the substrate side toward the metal layer; and
forming a plurality of holes aligned in a pattern corresponding to identification information, in the metal layer, during the irradiating the laser beam.

18. The display device manufacturing method of claim 17, wherein
the irradiating the laser beam is performed in a state in which the protective film is in contact with a stage.

19. The display device manufacturing method of claim 18, wherein
during the irradiating the laser beam, a hole penetrating the protective film is not formed, but dust generated by forming the hole penetrating the metal layer adheres to the protective film, and
the protective film is then peeled.

20. The display device manufacturing method of claim 19, wherein
the laser beam is a laser beam of a UV wavelength,
the substrate is a glass substrate, and
the metal layer is formed of at least one material of titanium, molybdenum, tungsten, and aluminum.
